(19) United States
(12) Patent Application Publication
(10) Pub. No.: US 2026/0027827 A1
(43) Pub. Date: Jan. 29, 2026

(54) MICRO-TRANSFER PRINTING FOR MEMS

(71) Applicant: X-FAB GLOBAL SERVICES GMBH, Erfurt (DE)

(72) Inventors: Yves DUFOUR, Fontainebleau (FR); Sebastian WICHT, Kranichfeld (DE); Steffen LEOPOLD, Ilmenau (DE)

(21) Appl. No.: 19/278,899

(22) Filed: Jul. 24, 2025

(30) Foreign Application Priority Data
Jul. 25, 2024 (DE) 102024121261.6

(51) Int. Cl. B41J 2/14; B81B 7/00; B81C 1/00

(52) U.S. Cl. CPC B41J 2/14298; B81B 7/008; B81C 1/0023; B81B 2201/052; B81B 2207/012; B81C 2203/0785

(57) ABSTRACT

A method of forming a semiconductor structure includes providing a semiconductor substrate, forming a micro-electromechanical structure (MEMS) device in and/or on the semiconductor substrate, and providing a semiconductor chiplet comprising a circuit configured to provide input for the MEMS device and/or to process output from the MEMS device. The method further includes micro-transfer printing the semiconductor chiplet onto the semiconductor substrate, and connecting the circuit to the MEMS device.

### CROSS-REFERENCE TO RELATED APPLICATION

This application claims priority to Germany patent application No. 102024121261.6 filed on Jul. 25, 2025 the entire contents of which are hereby incorporated by reference.

### TECHNICAL FIELD

The disclosure concerns micro-transfer printing for micro-electromechanical systems (MEMS).

### BACKGROUND

A piezoelectric MEMS system includes a MEMS section where a piezo stack is used to actuate the material and/or sense mechanical stress applied to the material, and an external electronic controller, typically including high voltage transistors. The MEMS section typically comprises an array of MEMS devices that can be connected to the electronics by external wiring.

For example, a inkjet print head may comprise such a MEMS system. The electronics include high voltage drivers on a separate die or board. The ink bearing MEMS elements (e.g. made of lead zirconate titanate, commonly known as PZT) are arranged close to the paper in a large array of dots. The dots are connected to the drivers with a wide ribbon cable.

For a large print head, the system can be very bulky and many wires are required. The array size is effectively limited by the ribbon cable. Hence, there is a need for an improved system, and in particular for large MEMS arrays.

### SUMMARY

Aspects of the present disclosure provide a semiconductor structure and a method for use in making such a structure as set out in the appended claims.

Certain embodiments now be described with reference to the accompanying drawings.

### BRIEF DESCRIPTION OF DRAWINGS

FIG. 1 shows a cross-sectional schematic diagram of a part of a print head comprising a semiconductor structure;

FIG. 2 shows a schematic cross-section of a chiplet;

FIG. 3 shows a schematic top view of an apparatus comprising a plurality of MEMS devices;

FIGS. 4A, 4B, 4C and 4D show subsequent schematic cross-sections of a semiconductor structure being processed;

FIGS. 5A, 5B, 5C and 5D show subsequent schematic cross-sections of a semiconductor structure being processed according to another embodiment;

FIGS. 6A, 6B and 6C show subsequent schematic cross-sections of a semiconductor structure being processed according to another embodiment; and

FIG. 7 shows a schematic diagram of a part of the semiconductor structure.

### DETAILED DESCRIPTION

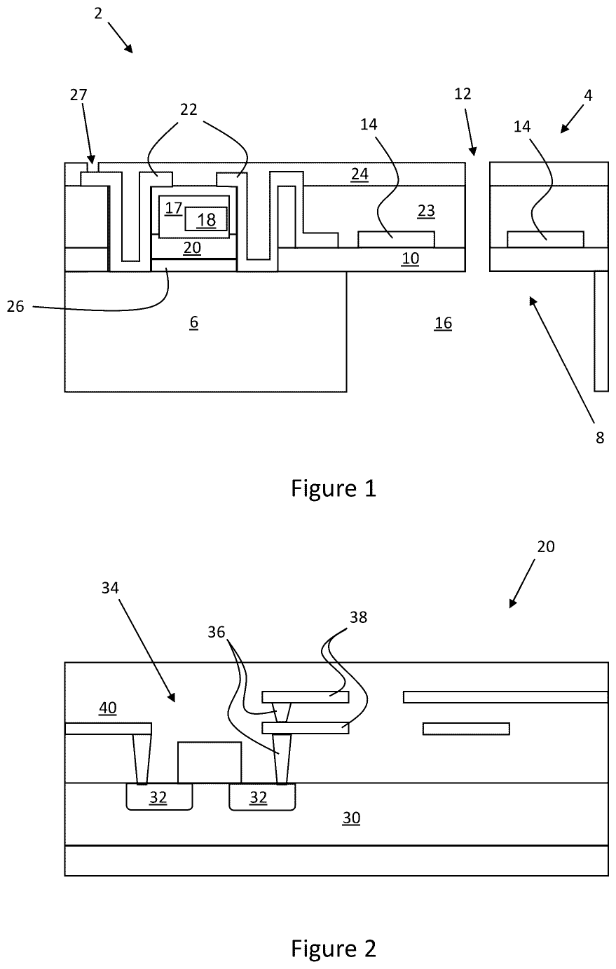

FIG. 1 shows a cross-sectional schematic diagram of a part of a print head comprising a semiconductor structure 2 comprising a micro-electromechanical structure (MEMS) device 4 formed in and on a semiconductor substrate 6.

The MEMS device comprises a membrane 8 comprising a membrane layer 10, with an aperture 12. The MEMS device further comprises a piezoelectric element 14 for actuating the membrane 8 by applying a voltage to the piezoelectric element 14. Typically, the piezoelectric element comprises a stack comprising two electrodes sandwiching piezoelectric material (e.g. Al(Sc)N). A cavity 16 behind the membrane is configured to hold ink, which can be dispensed through the aperture 12 by actuating the membrane 8 with the piezoelectric element 14. The semiconductor structure further comprises a circuit 17 comprising a driver 18 for driving the MEMS device 4 by providing electric signals to the MEMS device 4. The driver 18 comprises a plurality of active and passive components, such as transistors, diodes, resistors, capacitors and conductors. The driver 18 is configured to provide the input to the MEMS device 4. In other embodiments the circuit 17 may in addition or alternatively comprise a sensor circuit for receiving and processing output from the MEMS device 4. The print head comprises a plurality of drivers 18 and respective associated MEMS devices 4, wherein each MEMS device 4 provides one so called “nozzle” of the print head. For example, the print head may comprise 100 nozzles or more.

The driver 18 is located in/on a chiplet 20, being a part of a chip that has been removed from its native substrate (i.e. the substrate on which the chip was formed). Typically, the chiplet 20 comprises a plurality of drivers 18 for driving a plurality MEMS devices 4 (of which one is shown). The chiplet 20 has been transfer printed onto the semiconductor substrate 6 (the “target” substrate). The semiconductor substrate 6 is comprised by a MEMS wafer (i.e. a semiconductor wafer in which the MEMS devices are formed). The print head can be made of a single die. After micro-transfer printing the chiplet 20 onto the (MEMS) semiconductor substrate 6, the chiplet 20 is electrically connected to the MEMS device 4 by a redistribution layer (RDL) 22. The RDL 22 may comprises metal lines (e.g. copper) between the chiplet 20 and the MEMS device 4. The RDL 22 provides input and output connections to the driver 18. The chiplet 20 is typically attached to the substrate 6 by an adhesive layer 26, e.g. a glue layer.

The semiconductor structure 2 comprises a dielectric layer 23 (e.g. SiO2) on the membrane layer 10, and a passivation layer 24 covering both the MEMS device 4 and the chiplet 20. The passivation layer 24 may be a silicon nitride layer. Alternatively, the passivation layer may comprise bisbenzocyclobutane (BCB), e.g. having a thickness of about 2 μm to 3 μm, to provide a flat surface having a relatively low mechanical stiffness. The passivation layer 24 comprises opening 27 for connecting to the semiconductor structure 2. The passivation layer 24 provides a smooth upper surface, which allows the print head to be wiped clean. The dielectric layer 23 may have a thickness of about 500 nm and be patterned to provide connections. The dielectric layer 23 is patterned to facilitate the connection between the chiplet 20 and the MEMS device 4.

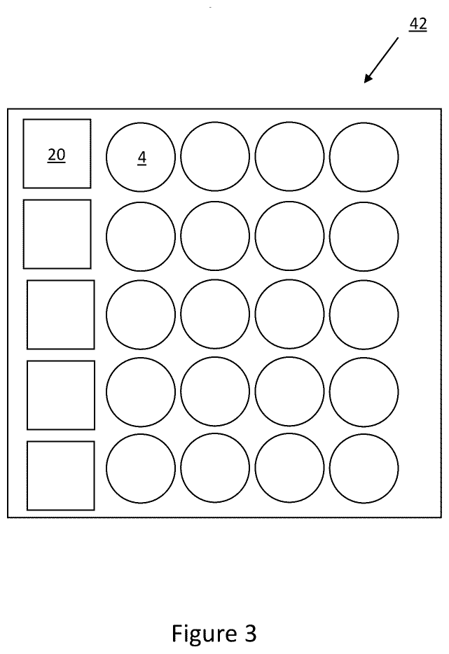

FIG. 2 shows a schematic cross-section of a chiplet 20, which may be the chiplet 20 described in relation to FIG. 1 above. The same reference numerals have been used for equivalent or similar features in different figures to aid understanding, and are not intended to limit the illustrated embodiments. The chiplet 20 comprises an active silicon layer 30, with doped regions 32 of a transistor 34. Vias 36 and metal layers 38 provide electrical connections and routing within the chiplet 20. The metal layers 38 are separated by dielectric layers 40 (typically silicon oxide layers). The transistor 34 together with other components (not shown) of the chiplet 20 form a driver for driving a MEMS device (not shown).

FIG. 3 shows a schematic top view of an apparatus 42 (e.g. a print head, or ultrasound transducer array) comprising a plurality of MEMS devices 4 and chiplets 20 connected to the MEMS devices. The apparatus 42 may be the print head described in relation to FIG. 1 above. Each chiplet 20 is configured to control a row of MEMS devices 4 of the apparatus 42.

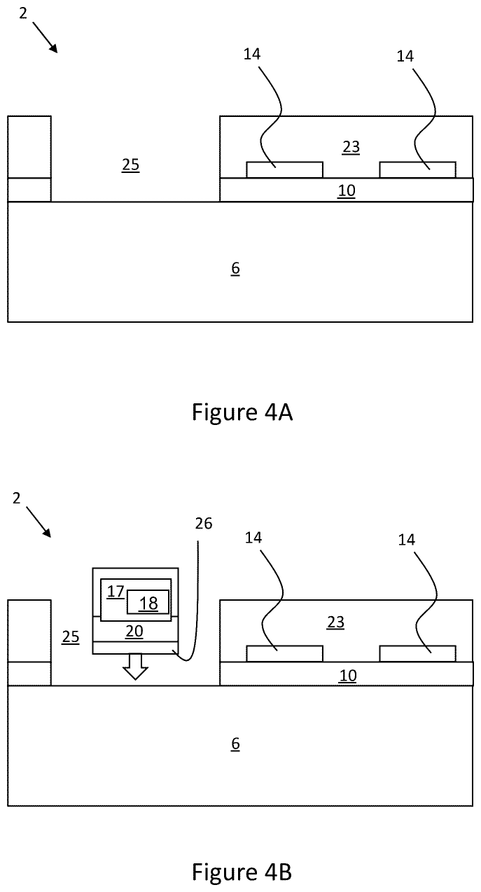

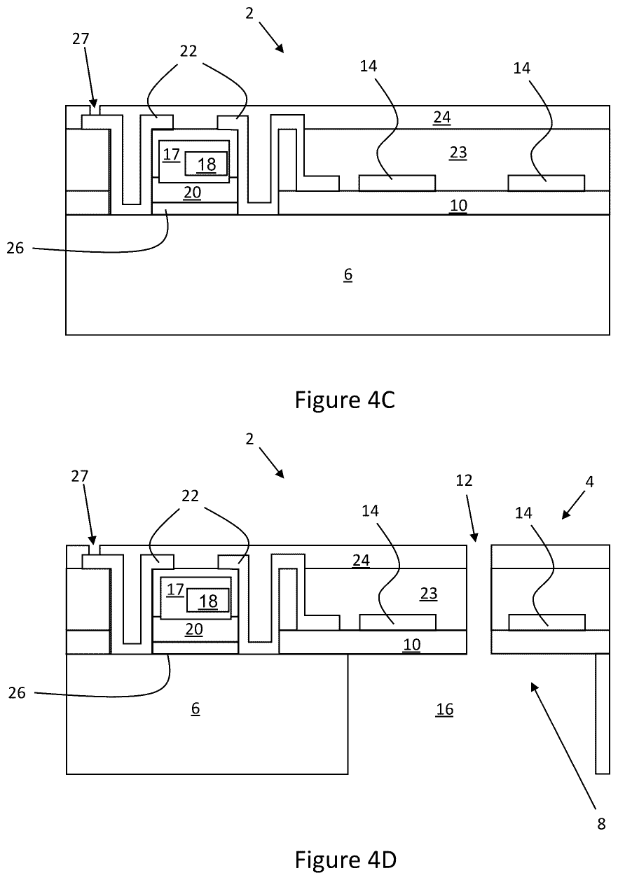

FIGS. 4A to 4D show subsequent schematic cross-sections of a semiconductor structure 2 being processed. In this embodiment, the chiplet 20 with the driver 18 is transfer printed onto the MEMS wafer in the middle of the MEMS processing. Specifically, the chiplet 20 is transfer printed after forming the piezoelectric element 14 and before forming the cavity 16 and aperture 12, which complete formation of the membrane 8.

In FIG. 4A, the semiconductor substrate 6 (i.e. the MEMS wafer) has been structured to form the piezoelectric element 14 and associated electronics (not shown), on the membrane layer 10 (e.g. comprising silicon oxide). A trench 25 is formed in the dielectric layer 23 and membrane layer 10, and may also extend into the substrate 6. For example, for a thicker chiplet 20 a trench 25 in the substrate 6 may be required, while for a thinner chiplet 20 the trench 25 may be shallower. For example, the trench 25 may be formed by photolithography using a photoresist mask and etching.

In FIG. 4B, the chiplet 20 is transfer printed onto the substrate 6 in the trench 25. The chiplet 20 comprises circuit 17 comprising the driver 18. For example, the chiplet 20 may be the chiplet described in relation to FIG. 2 above. The chiplet 20 may have been formed in a CMOS process, for example on a silicon on insulator (SOI) substrate. The chiplet 20 is placed in a trench 25 so the front (top) side of the print head can be kept flat and compatible with printer applications requiring print head wiping

In FIG. 4C, the RDL 22 is formed to connect the chiplet 20 to the piezoelectric element 14. A passivation layer 24 is deposited over the dielectric layer 23 and the chiplet 20. The passivation layer 24 may comprise silicon oxide. One or more openings 27 are formed in the passivation layer 24 for connections to the chiplet 20.

In FIG. 4D, the cavity 16 and aperture 12 are formed to release the membrane 8 and provide MEMS device 4. For example, the substrate 6 is back etched to form the cavity 16. One or more further etching steps can be used to provide aperture 12. The MEMS process/sequence is split into steps before and after the micro-transfer, which can help ensure that the final device has the right coating and fluidic properties. The piezoelectric element (e.g. a piezo stack) is provided before the micro-transfer process, while membrane structuring involving large etching on the front and/or back side of the wafer are done after the micro-transfer process. Thinned wafers with large etched volumes are brittle and it can therefore be advantageous to perform the associated process steps as late as possible. Also, by providing the actuator first, thermal stress on the micro-transferred chiplet 20 can be avoided.

In general, micro-transfer printing is a wafer level process where chiplets are extracted from a donor wafer (also referred to as a native or source wafer/substrate) and pasted on a target wafer. Then the RDL is formed to connect the chiplet to structures on the target wafer. Micro-transfer printing allows the assembly of non-compatible technologies on a single die and also for cost improvement, when chiplets from an expensive technology (e.g. CMOS) are transferred on to a larger (cheaper) wafer. The integration method at wafer level also allows a large number of connections between wafer and chiplets to be implemented efficiently.

The MEMS device 4, with the mechanical actuator, is relatively large and the manufacturing process involves a small number of layers (e.g. less than 10), while the chiplet 20 may have only a few high voltage transistors made in a complex process on an expensive SOI substrate and using upwards of 40 mask layers.

Micro-transfer printing allows the two dies to be combined in an efficient manner. In the case of CMOS chiplets transferred onto a MEMS wafer, a high density CMOS design can be connected to large and low density MEMS dies. Additionally, direct high density connections using the RDL (without off-chip wires) also allows the integration of large arrays of actuators, which need to be controlled individually by a CMOS driver. The global system then looks like an integrated CMOS/MEMS wafer.

MEMS can benefit from large geometries, large dies and low complexity. CMOS can provide high performance transistors for individual actuator control on a complex and expensive process. High voltage transistors can be used to provide the correct waveforms to the MEMS devices 4, low voltage transistors can be used for the control logic and serial to parallel interface, greatly reducing the wiring burden. The RDL associated with micro-transfer printing integration can replace the discrete wiring with a relatively fine pitch, compatible with large arrays.

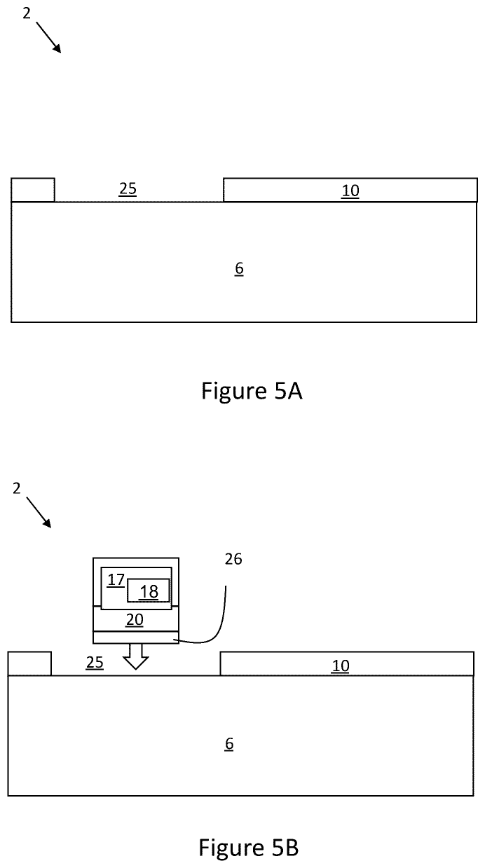

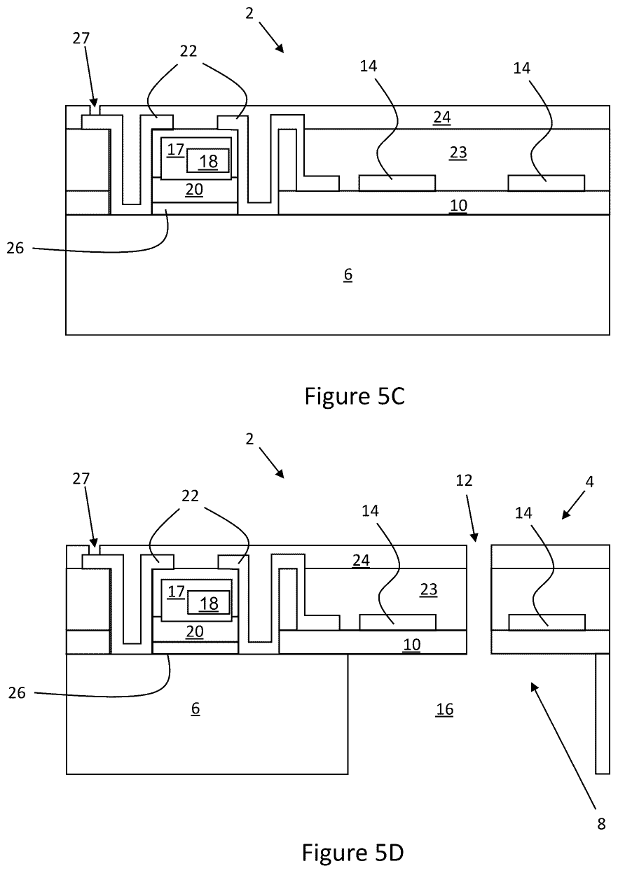

FIGS. 5A to 5D show subsequent schematic cross-sections of a semiconductor structure 2 being processed according to another embodiment, wherein the chiplet 20 is transfer printed onto the target substrate 6 before any MEMS processing.

In FIG. 5A, the semiconductor substrate 6 is provided with a membrane layer 10. A trench 25 is formed in the membrane layer 10. The trench may extend into the substrate 6.

In FIG. 5B, the chiplet 20 comprising the driver 18 is transfer printed onto the substrate 6. An adhesive layer 26 is be provided between the chiplet 20 and the substrate 6.

In FIG. 5C, the MEMS structure comprising piezoelectric element 14 is formed on the membrane layer 10, and the RDL 22 is formed to connect the chiplet 20 to the piezoelectric element 14. A passivation layer 24 is provided and openings 27 are formed in the passivation layer for connecting to the RDL 22.

In FIG. 5D, the cavity 16 and aperture 12 are formed to release the membrane 8 and provide/complete MEMS device 4. For example, the substrate 6 is back etched to form the cavity 16. One or more further etching steps can be used to provide the aperture 12.

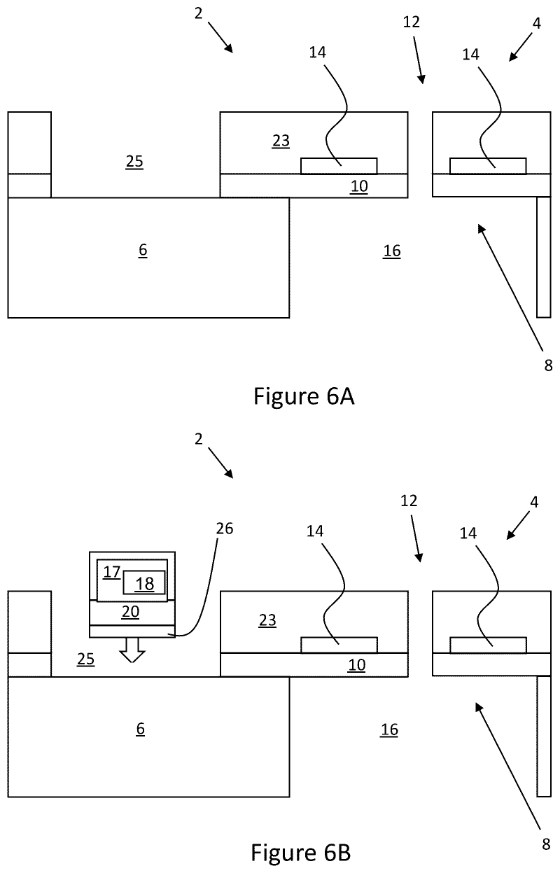

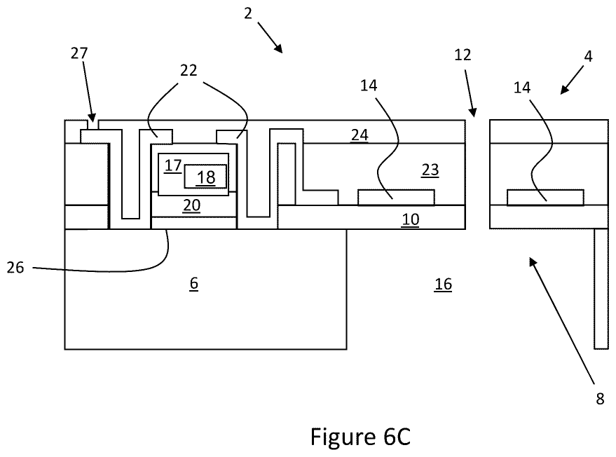

FIGS. 6A to 6C show subsequent schematic cross-sections of a semiconductor structure 2 being processed according to another embodiment, wherein the chiplet 20 is transfer printed onto the target substrate 6 after forming the MEMS device 4 on/in the substrate 6.

In FIG. 6A, the MEMS device 4, comprising the piezoelectric element 14 and membrane 8, is formed in/on the semiconductor substrate 6. Overlying dielectric layer 23 is formed on the membrane layer 10. A trench 25 is formed in the dielectric layer 23 and in the membrane layer 10. The trench may extend into the substrate 6.

In FIG. 6B, the chiplet 20 with the driver 18 is transfer printed onto the substrate 6 in the trench 25. An adhesive layer 26 can be provided between the chiplet 20 and the substrate 6.

In FIG. 6C, an RDL 22 is formed to connect the chiplet 20 to the MEMS device 4, allowing the driver 18 to drive the MEMS device 4 by applying a voltage to the piezoelectric element 14. A passivation layer 24 is provided over the chiplet 20 and MEMS device 4. One or more openings 27 are formed in the passivation layer 24 to provide connections to the chiplet 20 via the RDL 22.

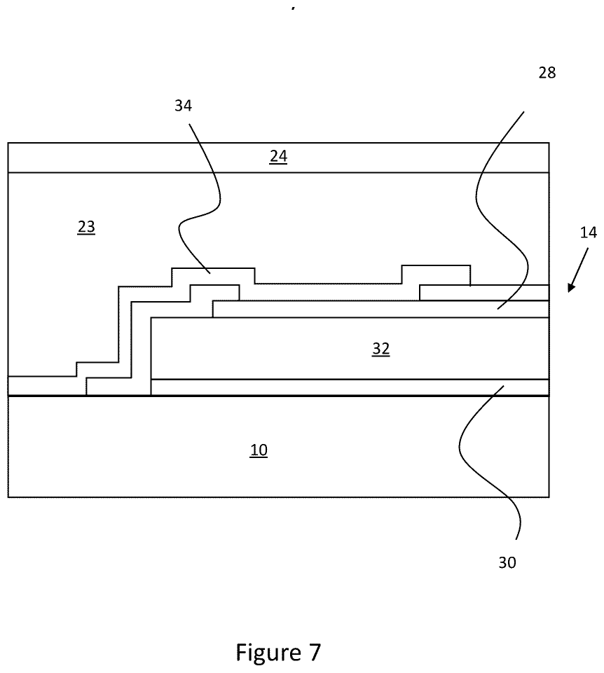

FIG. 7 shows a schematic diagram of a part of the semiconductor structure comprising the piezoelectric element 14 comprising a stack with a top electrode 28 and a bottom electrode 30 sandwiching a piezoelectric material 32 (e.g. PZT). Piezoelectric element is located on the membrane layer 10, and is arranged to actuate (e.g. bend) the membrane when a voltage is applied across the electrodes 28 and 30. The top electrode 28 is connected to metal layer 34 which in turn connects the piezoelectric element 14 to chiplet (not shown) via the RDL (not shown). The piezoelectric element 14 is covered by dielectric layer 23 and passivation layer 24.

In general, according to a first aspect, embodiments described herein provide a method of forming a semiconductor structure, the method comprising:
providing a semiconductor substrate;
forming a micro-electromechanical structure (MEMS) device in and/or on the semiconductor substrate;
providing a semiconductor chiplet comprising a circuit configured to provide input for the MEMS device and/or to process output from the MEMS device;
micro-transfer printing the semiconductor chiplet onto the semiconductor substrate; and
connecting the driver to the MEMS device.

The semiconductor structure may be a part of a print head, a capacitive MEMS ultrasonic transducer (CMUT), a piezoelectric MEMS ultrasonic transducer (PMUT), or another apparatus comprising MEMS technology. A print head, CMUT and PMUT all comprise an array of MEMS devices, each comprising a membrane that can be displaced and an actuator for displacing the membrane. For example, in the case of a PMUT, the MEMS device comprises a piezoelectric element for displacing the membrane in order to generate ultrasound. The semiconductor substrate can be referred to as the target substrate (on to which the chiplet is transfer printed). The semiconductor substrate may also be referred to as the MEMS wafer, as the MEMS device is formed in and/or on the semiconductor substrate. In general, the membrane of the MEMS device is formed by back etching the semiconductor substrate. This allows the MEMS technology to be efficiently combined with another (higher cost/complexity) technology (e.g. CMOS).

The method may comprise forming a plurality of further MEMS devices in and/or on the semiconductor substrate, wherein the chiplet comprises a corresponding plurality of circuits for driving the plurality of further MEMS devices and/or to process output from the plurality of further MEMS devices. For example, each chiplet may comprise a plurality of drivers associated with respective MEMS devices, and the method may comprise micro-transfer printing a plurality of such chiplets onto the same semiconductor substrate. For example, each chiplet may comprise between five and ten drivers.

The circuit(s) typically comprise a plurality of CMOS devices. For example, transistors, such as high voltage transistors, formed in a CMOS process.

The step of providing the semiconductor chiplet may comprise:
providing a second semiconductor substrate;
forming the circuit, comprising one or more semiconductor devices in and/or on the second semiconductor substrate; and
performing an etching step to release the semiconductor chiplet from the second semiconductor substrate.

The second semiconductor substrate may be a silicon on insulator (SOI) substrate. The second substrate is the native substrate of the chiplet, on which it is formed before being lifted off during the micro-transfer printing process. A SOI substrate comprises a silicon handle wafer and an epitaxial silicon layer (also referred to as the active silicon layer), separated by an oxide layer (referred to as the buried oxide, BOX, layer). During the micro-transfer process, the chiplet is lifted off the native substrate.

The step of micro-transfer printing may comprise forming a trench on and/or in the substrate and placing the semiconductor chiplet in the trench. For example, the trench may be formed in a membrane layer and optionally one or more dielectric layers on the semiconductor substrate. The trench may also extend into the semiconductor substrate and may be lined with silicon oxide. The chiplet can be attached directly to the semiconductor substrate (or a silicon oxide layer lining the trench), for example using an adhesive layer.

Connecting the driver to the MEMS device typically comprises forming a redistribution layer (RDL). The RDL can be formed by depositing a metal layer (e.g. copper) onto the chiplet and MEMS structure and patterning the metal layer to form metal lines. Alternatively, connecting the driver to the MEMS device may comprise a dielectric or organic material deposition after the micro-transfer printing process, followed by flattening, via etching and standard metal deposition or lift off.

The step of forming the MEMS device in and/or on the semiconductor substrate may comprise:
providing an actuator on the semiconductor substrate; and
etching the semiconductor substrate to form a membrane, wherein the actuator is arranged to actuate the membrane. The actuator may comprises a piezoelectric element. For example, the piezoelectric element may comprise a so called piezo stack comprising a piezoelectric material sandwiched by two electrodes. The electrodes can then be connected to the driver via the RDL. The piezoelectric material may be, for example, PZT or Al(Sc)N.

The step of micro-transfer printing the semiconductor chiplet may be performed after the step of providing the actuator and before the step of etching the semiconductor substrate to form the membrane.

Alternatively, the step of micro-transfer printing the semiconductor chiplet can be performed before the step of forming the MEMS device. That is, the chiplet may be transfer printed onto the substrate before any MEMS processing.

Alternatively, the step of micro-transfer printing the semiconductor chiplet can be performed after the step of forming the MEMS device. That is the MEMS device is fully formed (without driver electronics) before the chiplet is provided on the substrate and then connected to the MEMS device.

The MEMS device may comprise a membrane configured to actuate a fluid (e.g. ink in the case of an inkjet print head) in contact with the membrane. For example, the MEMS device may provide a nozzle for an inkjet print head and may comprise a membrane comprising an aperture for releasing ink. In another embodiment, the nozzle may be located elsewhere (not formed directly in the membrane), and the membrane may be used to pump the ink to the nozzle. The method may comprise applying an ink coating to the MEMS device. For example, the ink coating may comprise a hydrophobic coating layer.

According to a second aspect, embodiments described herein provide a semiconductor structure comprising:
A semiconductor substrate;
A MEMS device located in and/or on the semiconductor substrate;
A chiplet attached to the semiconductor substrate, wherein the chiplet is connected to the MEMS device and comprises a circuit configured to provide input to the MEMS device and/or to process output from the MEMS device.

The semiconductor structure may be formed according to the method according to the first aspect described above.

The circuit may comprises a driver for driving the MEMS device and/or a sensor circuit for sensing with the MEMS device.

The MEMS device may comprise an actuator and a membrane comprising a part of a membrane layer, wherein the actuator is configured to actuate the membrane. The driver may comprise a plurality of complementary metal oxide semiconductor (CMOS) devices. For example, the driver may comprise a plurality of high voltage transistors.

The chiplet may comprise a part of a silicon on insulator (SOI) substrate. That is, the chiplet may have been formed on/in a SOI substrate being the native substrate of the chiplet. A part of this SOI substrate is lifted to provide the chiplet. The chiplet may be attached to the substrate by an adhesive layer. The chiplet can be located in a trench on the semiconductor substrate. The trench may extend through one or more layers on the semiconductor substrate and may extend into the semiconductor substrate. This allows for a more planar topography, which can be particularly beneficial for a print head. The chiplet may also be formed on other types of semiconductor substrates, such as GaN or SiC.

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein.

What is claimed is:

1. A method of forming a semiconductor structure, the method comprising:
providing a semiconductor substrate;
forming a micro-electromechanical structure (MEMS) device in and/or on the semiconductor substrate;
providing a semiconductor chiplet comprising a circuit configured to provide input for the MEMS device and/or to process output from the MEMS device;
micro-transfer printing the semiconductor chiplet onto the semiconductor substrate; and
connecting the circuit to the MEMS device.

2. A method according to claim 1, wherein the circuit comprises a driver for driving the MEMS device and/or a sensor circuit for sensing with the MEMS device.

3. A method according to claim 1, further comprising forming a plurality of further MEMS devices in and/or on the semiconductor substrate, wherein the semiconductor chiplet comprises a corresponding plurality of further circuits configured to provide input for the plurality of further MEMS devices and/or to process output from the plurality of further MEMS devices.

4. A method according to claim 1, wherein the circuit comprises a plurality of CMOS devices.

5. A method according to claim 1, wherein providing the semiconductor chiplet comprises:
providing a second semiconductor substrate;
forming the circuit, comprising one or more semiconductor devices in and/or on the second semiconductor substrate; and
performing an etching step to release the semiconductor chiplet from the second semiconductor substrate.

6. A method according to claim 5, wherein the second semiconductor substrate is a silicon on insulator (SOI) substrate.

7. A method according to claim 1, wherein the step of micro-transfer printing the semiconductor chiplet comprises forming a trench on and/or in the substrate and placing the semiconductor chiplet in the trench.

8. A method according to claim 1, wherein connecting the circuit to the MEMS device comprises forming a redistribution layer (RDL).

9. A method according to claim 1, wherein the step of forming the MEMS device in and/or on the semiconductor substrate comprises:
providing an actuator on the semiconductor substrate; and
etching the semiconductor substrate to form a membrane, wherein the actuator is arranged to actuate the membrane.

10. A method according to claim 9, wherein the actuator comprises a piezoelectric element.

11. A method according to claim 9, wherein the step of micro-transfer printing the semiconductor chiplet is performed after the step of providing the actuator and before the step of etching the semiconductor substrate to form the membrane.

12. A method according to claim 1, wherein the step of micro-transfer printing the semiconductor chiplet is performed before the step of forming the MEMS device.

13. A method according to claim 1, wherein the step of micro-transfer printing the semiconductor chiplet is performed after the step of forming the MEMS device.

14. A method according to claim 1, wherein the MEMS device comprises a membrane configured to actuate a fluid in contact with the membrane.

15. A method according to claim 14, further comprising applying an ink coating to the MEMS device.

16. A semiconductor structure comprising:
a semiconductor substrate;
a MEMS device located in and/or on the semiconductor substrate; and
a chiplet attached to the semiconductor substrate, wherein the chiplet is connected to the MEMS device and comprises a circuit configured to provide input to the MEMS device and/or to process output from the MEMS device.

17. A semiconductor structure according to claim 16, wherein the circuit comprises a driver for driving the MEMS device and/or a sensor circuit for sensing with the MEMS device.

18. A semiconductor structure according to the claim 16, wherein the MEMS device comprises an actuator and a membrane comprising a part of a membrane layer, wherein the actuator is configured to actuate the membrane.

19. A semiconductor structure according to claim 18, wherein the actuator comprises a piezoelectric element.

20. A semiconductor structure according to claim 18, wherein the MEMS device comprises an ink coating on at least a part of the membrane.

21. A semiconductor structure according to claim 16, wherein the circuit comprises a plurality of complementary metal oxide semiconductor (CMOS) devices.

22. A semiconductor structure according to claim 16, wherein the chiplet comprises a part of a silicon on insulator (SOI) substrate.

23. A semiconductor structure according to claim 16, wherein the chiplet is attached to the substrate by an adhesive layer.

24. A semiconductor structure according to claim 16, wherein the chiplet is located in a trench on the semiconductor substrate.

25. An inkjet print head comprising a semiconductor structure according to claim 16.
